(19) United States
(12) Patent Application Publication
(10) Pub. No.: US 2024/0096947 A1
(43) Pub. Date: Mar. 21, 2024

(54) COMPOSITE NANOSHEET TUNNEL TRANSISTORS

(71) Applicant: International Business Machines Corporation, Armonk, NY (US)

(72) Inventors: Kirsten Emilie Moselund, Rüschlikon (CH); Nicolas Jean Loubet, GUILDERLAND, NY (US); Bogdan Cezar Zota, Rüschlikon (CH); Shogo Mochizuki, Mechanicville, NY (US)

(21) Appl. No.: 17/933,882

(22) Filed: Sep. 21, 2022

(51) Int. Cl. H01L 29/06; H01L 21/8238; H01L 29/20; H01L 29/66; H01L 29/775; H01L 29/786

(52) U.S. Cl. CPC H01L 29/0673; H01L 21/823807; H01L 21/823814; H01L 29/20; H01L 29/66439; H01L 29/775; H01L 29/78696

(57) ABSTRACT

Embodiments of the present invention are directed to the implantation of composite tunnel field effect transistors (TFETs) in a nanosheet process. In a non-limiting embodiment of the invention, a first source or drain region is formed having a first composition and a first doping type. A second source or drain region is formed having a second composition and a second doping type opposite the first doping type. A first composite channel structure is formed between the first source or drain region and the second source or drain region. The first composite channel structure includes a first nanosheet trimmed to expose extension portions of the first source or drain region and extension portions of the second source or drain region. The first composite channel structure further includes a first channel epitaxy wrapping around the trimmed first nanosheet. The first channel epitaxy is connected laterally to the extension portions.

### BACKGROUND

The present invention generally relates to fabrication methods and resulting structures for semiconductor devices, and more specifically, to processing methods and resulting structures for the implantation of composite tunnel field effect transistors (TFETs) in a nanosheet process.

Known metal oxide semiconductor field effect transistor (MOSFET) fabrication techniques include process flows for constructing planar field effect transistors (FETs). A planar FET includes a substrate (also referred to as a silicon slab); a gate formed over the substrate; source and drain regions formed on opposite ends of the gate; and a channel region near the surface of the substrate under the gate. The channel region electrically connects the source region to the drain region while the gate controls the current in the channel. The gate voltage controls whether the path from drain to source is an open circuit (“off”) or a resistive path (“on”).

In recent years, research has been devoted to the development of nonplanar transistor architectures. For example, gate-all-around (GAA) transistors (also referred to as nanosheet FETs and nanowire FETs) include a non-planar architecture that provides increased device density and some increased performance over lateral devices. In nanosheet FETs, in contrast to conventional planar FETs, the channel is implemented as a plurality of stacked and spaced-apart nanosheets. The gate stack wraps around the full perimeter of each nanosheet, thus enabling fuller depletion in the channel region, and also reducing short-channel effects due to steeper subthreshold swing (SS) and smaller drain induced barrier lowering (DIBL).

### SUMMARY

Embodiments of the invention are directed to the implantation of composite tunnel field effect transistors (TFETs) in a nanosheet process. A non-limiting example of the method includes forming a first source or drain region having a first composition and a first doping type and forming a second source or drain region having a second composition and a second doping type opposite the first doping type. A first composite channel structure is formed between the first source or drain region and the second source or drain region. The first composite channel structure includes a first nanosheet trimmed to expose extension portions of the first source or drain region and extension portions of the second source or drain region. The first composite channel structure further includes a first channel epitaxy wrapping around the trimmed first nanosheet. The first channel epitaxy is connected laterally to the extension portions.

Embodiments of the invention are directed to a semiconductor structure. A non-limiting example of the semiconductor structure includes a first source or drain region having a first composition and a first doping type and a second source or drain region having a second composition and a second doping type opposite the first doping type. A first composite channel structure is between the first source or drain region and the second source or drain region. The first composite channel structure includes a first nanosheet trimmed to expose extension portions of the first source or drain region and extension portions of the second source or drain region. The first composite channel structure further includes a first channel epitaxy wrapping around the trimmed first nanosheet. The first channel epitaxy is connected laterally to the extension portions.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a first cross-sectional view (across gate in a channel region) of a semiconductor wafer after an initial set of processing operations according to one or more embodiments of the invention;

FIG. 1B depicts a second cross-sectional view (along gate in a channel region) of the semiconductor wafer of FIG. 1A after the initial set of processing operations according to one or more embodiments of the invention;

FIG. 2A depicts an across-gate cross-sectional view of the semiconductor wafer after a processing operation according to one or more embodiments of the invention;

FIG. 2B depicts an along-gate cross-sectional view of the semiconductor wafer of FIG. 2A after the processing operation according to one or more embodiments of the invention;

FIG. 3A depicts an across-gate cross-sectional view of the semiconductor wafer after a processing operation according to one or more embodiments of the invention;

FIG. 3B depicts an along-gate cross-sectional view of the semiconductor wafer of FIG. 3A after the processing operation according to one or more embodiments of the invention;

FIG. 4A depicts an across-gate cross-sectional view of the semiconductor wafer after a processing operation according to one or more embodiments of the invention;

FIG. 4B depicts an along-gate cross-sectional view of the semiconductor wafer of FIG. 4A after the processing operation according to one or more embodiments of the invention;

FIG. 4C depicts an exemplary channel profile in accordance with one or more embodiments;

FIG. 5A depicts an across-gate cross-sectional view of the semiconductor wafer after a processing operation according to one or more embodiments of the invention;

FIG. 5B depicts an along-gate cross-sectional view of the semiconductor wafer of FIG. 5A after the processing operation according to one or more embodiments of the invention;

FIG. 6A depicts an across-gate cross-sectional view of the semiconductor wafer after a processing operation according to one or more embodiments of the invention;

FIG. 6B depicts an along-gate cross-sectional view of the semiconductor wafer of FIG. 6A after the processing operation according to one or more embodiments of the invention; and

FIG. 7 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

There are several nonplanar transistor architectures for scaling transistors beyond the 7 nm node, but each is currently limited due to various factors. One such architecture is the so-called gate all around (GAA) field effect transistor (FET), sometimes referred to as a nanosheet FET or a nanowire FET. To increase the available computing power per unit area, GAA FET devices vertically stack channels over a shared substrate footprint. The resultant transistor offers several improvements over planar and fin-type devices, such as an increase in gate control, allowing for lower threshold voltages. Other improvements include variable device widths (additional design flexibility) and longer device widths (improved power, performance, area, cost, collectively PPAC).

As transistor fabrication continues to develop, non-MOSFET architectures are also being investigated. The tunnel field effect transistor (TFET), for example, offers a modified switching mechanism when compared to MOSFET transistors. TFETs switch by modulating quantum tunneling through a barrier rather than by modulating thermionic emission over a barrier as in traditional MOSFETs. TFETs provide the potential for lower power operation than MOSFETs due to the possibility of achieving a steeper subthreshold swing (lower even than thermal limit of 60 mV/decade at room-temperature). Steeper subthreshold swings are also predicted, enabling power supply (VDD) scaling down to 0.3 V. TFET fabrication is challenging, however, and efforts are ongoing to design fabrication schemes and structures that are suitable for scaled production. One challenge is the difficulty in providing the different channel/source combinations that are required for n- and p-channel devices in TFET devices.

Turning now to an overview of aspects of the present invention, one or more embodiments of the invention address the above-described shortcomings by providing fabrication methods and resulting structures for the implantation of composite TFETs in a nanosheet process. TFETs fabricated according to one or more embodiments share the nanosheet integration scheme through channel release. After channel release, a sequential regrowth process is employed to form two source/drain regions having different compositions and opposite doping polarities. Inner spacers between the two source/drain regions are recessed to expose the extension epitaxy (junction) and a first channel region (i.e., the channel between the two source/drain regions) is trimmed. A first channel epitaxy, connected laterally to the junction, is selectively grown from the trimmed channel region. The first channel epitaxy and the trimmed channel region (also referred to as a mandrel or template) together define a composite channel of the TFET. The first channel region is blocked and a similar process is used to form a second channel epitaxy on a second channel region (i.e., one or both of the channels opposite the two source/drain regions). The second channel epitaxy and the trimmed second channel region similarly define a second composite channel of the TFET.

Notably, the first channel epitaxy and the second channel epitaxy can be made of different materials. For example, a p-TFET can be formed using materials such as GaAsSb, while an n-TFET can be formed using materials such as InGaAs. In this manner, a complementary TFET having both a p-TFET and an n-TFET can be fabricated. Advantageously, TFETs formed according to one or more embodiments benefit greatly from the improved electrostatics and self-alignment offered by a nanosheet-based process, as TFETs are more sensitive to electrostatics and self-alignment than traditional MOSFETs. Moreover, TFETs formed according to one or more embodiments offer a higher effective capacitance without increasing device height (i.e., the nanosheet stack height is unchanged from nanosheet process flow). Other advantages include a minimal impact on external resistance as the source/drain epitaxy has the same volume as in the nanosheet process flow, roughly a double (2x) increase in effective gate length (Weft) as compared to other TFET architectures, the ability to integrate into current nanosheet fabrication schemes (up to channel release and cladding epitaxy), and source/drain re-use in complementary devices (e.g., for two different source/drain regrowths, the source for the n-TFET can serve as the drain for the p-TFET, and vice-versa).

In some embodiments, the relatively thin channel epitaxy layers are maintained on top of the original nanosheets (e.g., silicon nanosheets) in the final device. This approach improves mechanical stability and allows for even thinner layers. Alternatively, in some embodiments, the channel epitaxy layers themselves are released by selectively removing the underlying trimmed channel regions (i.e., the underlying silicon mandral or template). This approach enables a nanowire configuration where portions of the gate stack replace the removed, underlying channel regions. In either case, the gate stack(s) over the channels can be completed concurrently (i.e., a shared gate configuration) or separately (i.e., separate gate configuration). Separate gate stack constructions allow for independent gate stack optimizations, while concurrent gate stack constructions are generally simpler.

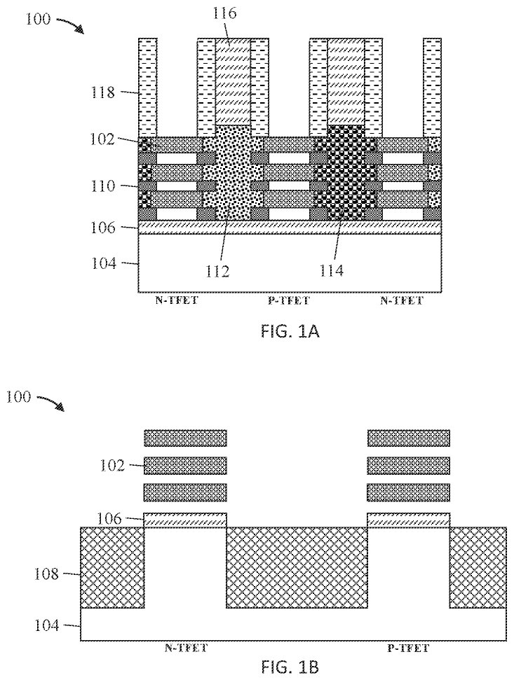

Turning now to a more detailed description of fabrication operations and resulting structures according to aspects of the invention, FIG. 1A depicts a first cross-sectional view (across gate in a channel region) of a semiconductor wafer 100 after an initial set of fabrication operations have been applied as part of a method of fabricating a final semiconductor device according to one or more embodiments of the invention. FIG. 1B depicts a second cross-sectional view (along gate in the channel region) of the semiconductor wafer 100 of FIG. 1A.

As shown in FIG. 1A, a plurality of nanosheets 102 are formed over a substrate 104. For ease of discussion, reference is made to operations performed on and to nanosheet stacks having three nanosheets (e.g., the three nanosheets 102 in each nanosheet stack shown in FIG. 1A). It is understood, however, that each nanosheet stack can include any number of nanosheets. For example, nanosheet stacks can include two nanosheets, five nanosheets, eight nanosheets, 30 nanosheets (e.g., 3D NAND), or any number of nanosheets. Moreover, it is not necessary that each nanosheet stack have a same number of nanosheets 102, and other configurations having any distribution of nanosheets is within the contemplated scope of this disclosure.

The nanosheets 102 and the substrate 104 can be made of any suitable semiconductor material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlinAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. The nanosheets 102 and the substrate 104 can be made of the same, or different, semiconductor materials. In some embodiments, the nanosheets 102 have a thickness of about 5 nm to about 15 nm, for example 10 nm, although other thicknesses are within the contemplated scope of this disclosure.

In some embodiments, the nanosheets 102 and the substrate 104 are separated by a bottom isolation structure 106. The bottom isolation structure 106 can be made of any suitable dielectric material, such as, for example, silicon oxide, silicon nitride, SiON, SiC, SiOCN, and SiBCN.

As shown in FIG. 1B, portions of the substrate 104 can be recessed to define a cavity (not separately shown). A shallow trench isolation (STI) region 108 can be formed by refilling the cavity with dielectrics. The STI region 108 can be made of any suitable dielectric material, such as, for example, silicon oxide, silicon nitride, SiON, SiC, SiOCN, and SiBCN.

As further shown in FIG. 1A, FEOL fabrication processes are used to form inner spacers 110, first source/drain regions 112, second source/drain regions 114, an interlayer dielectric 116, and gate spacers 118.

In some embodiments, the source/drain regions 112, 114 are epitaxially grown or otherwise formed from exposed sidewalls of the nanosheets 102. In some embodiments, the first source/drain regions 112 and the second source/drain regions 114 are made from different epitaxial materials. In some embodiments, the first source/drain regions 112 include dopants having a first doping type (e.g., n-type or p-type) and the second source/drain regions 114 include dopants having a second doping type opposite the first doping type (e.g., p-type or n-type), allowing for complementary transistor architectures (e.g., CMOS). For example, the first source/drain regions 112 can include InGaAs having n-type dopants (e.g., P, As, Sb, etc.) and the second source/drain regions 114 can include GaAsSb having p-type dopants (e.g., B, In, etc.). While shown having a particular complementary transistor structure (i.e., first and third nanosheet stacks define N-TFET transistors, while the second, middle nanosheet stack defines a P-TFET transistor) for ease of illustration and discussion, the particular arrangement of P-type and N-type devices is not meant to be particularly limited. Other configurations (e.g., P-TFET, N-TFET, P-TFET, all N-TFET, all P-TFET, etc.) are within the contemplated scope of this disclosure and can be achieved using the processes described herein.

In some embodiments, the interlayer dielectric 116 is deposited or otherwise formed on the source/drain regions 112, 114. The interlayer dielectric 116 can be made of any suitable dielectric material, such as, for example, oxides, a low-k dielectric, nitrides, silicon nitride, silicon oxide, SiON, SiC, SiOCN, and SiBCN.

In some embodiments, the gate spacers 118 are formed on sidewalls of a sacrificial gate (also referred to as a dummy gate, not separately shown). This process can be referred to as the gate spacer module. The gate spacers 118 can be made of any suitable dielectric material, such as, for example, silicon oxide, silicon nitride, silicon carbide, hydrogenated silicon carbonitrides, silicon oxynitrides, and silicon borocarbonitrides, although other dielectrics are within the contemplated scope of this disclosure. In some embodiments, spacer material is deposited over the semiconductor wafer 100 and patterned using an anisotropic etch, for example, a reactive ion etch (RIE).

In some embodiments, sacrificial layers (not separately shown) formed on and below the nanosheets 102 are recessed and the inner spacers 110 are formed in the recess. In some embodiments, the sacrificial layers are recessed selective to the nanosheets 102. The inner spacers 110 can be made of any suitable dielectric material, such as, for example, silicon oxide, silicon nitride, SiON, SiC, SiOCN, and SiBCN.

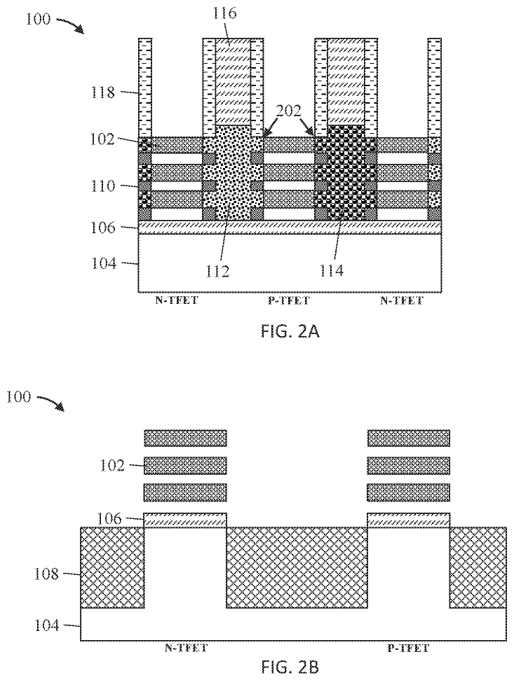

FIGS. 2A and 2B depict across-gate, and along-gate cross-sectional views, respectively, of the semiconductor wafer 100 after a processing operation according to one or more embodiments. As shown in FIG. 2A, the inner spacers 110 and the gate spacers 118 are recessed to expose extension portions 202 of the source/drain regions 112, 114. The inner spacers 110 and the gate spacers 118 can be recessed using a wet etch, a dry etch, or a combination of sequential wet and/or dry etches. In some embodiments, the inner spacers 110 and the gate spacers 118 are recessed selective to the nanosheets 102.

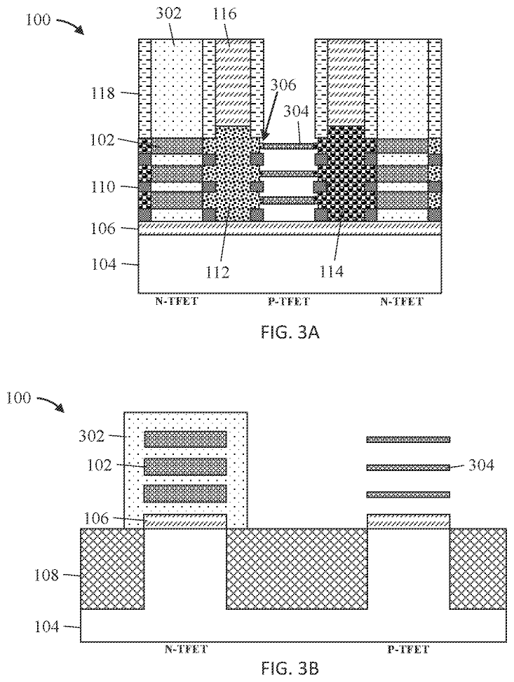

FIGS. 3A and 3B depict across-gate, and along-gate cross-sectional views, respectively, of the semiconductor wafer 100 after a processing operation according to one or more embodiments. As shown in FIGS. 3A and 3B, a block 302 (also referred to as a mask) can be formed over a portion of the nanosheets 102 in regions of the substrate 104 defining TFETs having a first polarity (e.g., the N-TFETs, as shown), exposing a channel region of one or more devices having a second, opposite polarity (e.g., the P-TFET, as shown). As used herein, a “channel region” refers to the portion of a nanosheet over which a gate is formed, and through which current passes from source to drain in the final device.

The exposed portion of the nanosheets 102 are trimmed (thinned) to define trimmed channel regions 304. The nanosheets 102 can be trimmed using, for example, a wet etch, a dry etch, or a combination of sequential wet and/or dry etches. In some embodiments, extension portions 202 of the source/drain regions 112, 114 are also trimmed during this process, defining cavities 306.

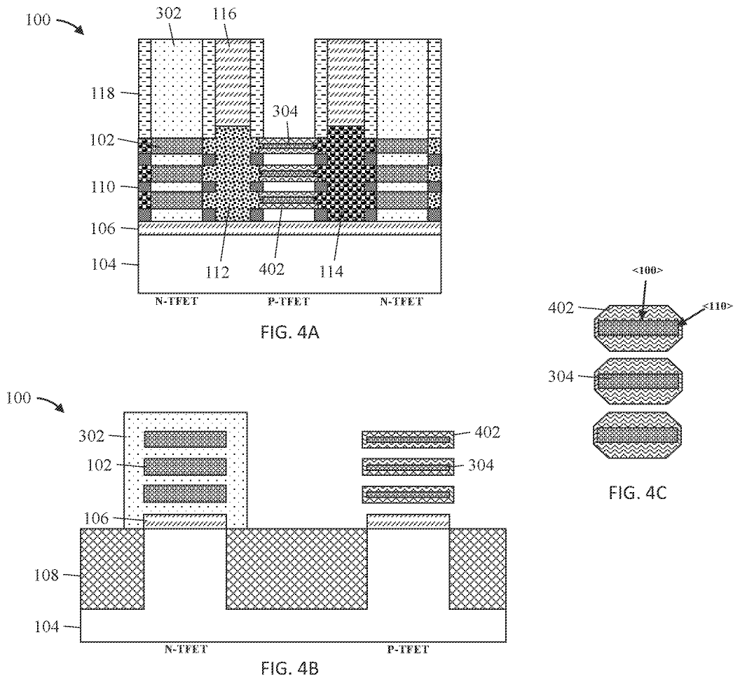

FIGS. 4A and 4B depict across-gate, and along-gate cross-sectional views, respectively, of the semiconductor wafer 100 after a processing operation according to one or more embodiments. As shown in FIGS. 4A and 4B, a first channel epitaxy 402 is formed over the trimmed channel regions 304. The materials selected for the first channel epitaxy 402 can vary depending on the desired polarity of the respective region of the substrate 104. For P-TFETs, for example, the first channel epitaxy 402 can be made of i-GaAsSb. For N-TFETs, for example, the first channel epitaxy 402 can be made of i-InGaAs.

In some embodiments, the first channel epitaxy 402 is epitaxially grown from the surface of the trimmed channel regions 304. In some embodiments, the first channel epitaxy 402 is formed by epitaxy cladding nucleation around the trimmed channel regions 304. In some embodiments, the first channel epitaxy 402 is selectively grown from the surface of the trimmed channel regions 304. In some embodiments, the first channel epitaxy 402 is preferentially grown from the <100> surface of the trimmed channel regions 304, rather than from the <110> surface. FIG. 3C illustrates an example cross-sectional profile of the first channel epitaxy 402 when preferentially grown from the <100> surface of the trimmed channel regions 304.

In some embodiments, the first channel epitaxy 402 extends to connect laterally to the extension portions 202 of the source/drain regions 112, 114. In other words, the first channel epitaxy 402 can fill the cavities 306 (FIG. 3A). In some embodiments, the first channel epitaxy 402 and the trimmed channel regions 304 together define a composite channel of the semiconductor wafer 100.

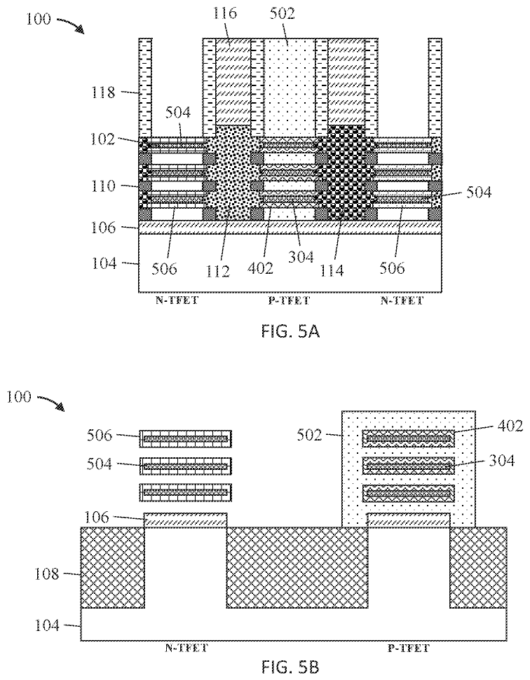

FIGS. 5A and 5B depict across-gate, and along-gate cross-sectional views, respectively, of the semiconductor wafer 100 after a processing operation according to one or more embodiments. As shown in FIGS. 5A and 5B, the block 302 can be removed and a new block 502 can be formed over a portion of the nanosheets 102 in regions of the substrate 104 defining TFETs having a second polarity (e.g., the P-TFETs, as shown), exposing the channel region of the one or more devices having the first polarity (e.g., the N-TFET, as shown).

The exposed portion of the nanosheets 102 are trimmed (thinned) to define second trimmed channel regions 504. The nanosheets 102 can be trimmed in a similar manner as described previously with respect to the trimmed channel regions 304 (FIG. 3A). In some embodiments, extension portions 202 of the source/drain regions 112, 114 are also trimmed during this process, defining cavities (not separately shown).

As further shown in FIGS. 5A and 5B, a second channel epitaxy 506 is formed over the second trimmed channel regions 504. The materials selected for the second channel epitaxy 506 can vary depending on the desired polarity of the respective region of the substrate 104. For P-TFETs, for example, the second channel epitaxy 506 can be made of i-GaAsSb. For N-TFETs, for example, the second channel epitaxy 506 can be made of i-InGaAs.

In some embodiments, the second channel epitaxy 506 is epitaxially grown from the surface of the second trimmed channel regions 504. In some embodiments, the second channel epitaxy 506 is formed by epitaxy cladding nucleation around the second trimmed channel regions 504. In some embodiments, the second channel epitaxy 506 is selectively grown from the surface of the second trimmed channel regions 504. In some embodiments, the second channel epitaxy 506 is preferentially grown from the <100> surface of the second trimmed channel regions 504, rather than from the <110> surface. FIG. 4C illustrates an exemplary channel profile when the second channel epitaxy 506 is preferentially grown from the <100> surface.

In some embodiments, the second channel epitaxy 506 extends to connect laterally to extension portions 202 of the source/drain regions 112, 114. In other words, the second channel epitaxy 506 can fill cavities in the source/drain regions 112, 114, in a similar manner as described previously with respect to the first channel epitaxy 402 (FIG. 4A). In some embodiments, the second channel epitaxy 506 and the second trimmed channel regions 504 together define a second composite channel of the semiconductor wafer 100.

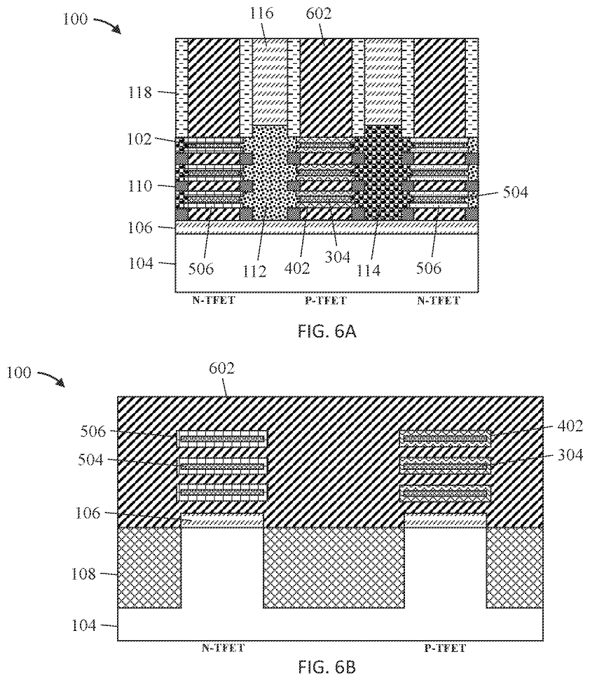

FIGS. 6A and 6B depict across-gate, and along-gate cross-sectional views, respectively, of the semiconductor wafer 100 after a processing operation according to one or more embodiments. As shown in FIGS. 6A and 6B, the block 502 can be removed and a conductive gate(s) 602 can be formed over channel regions of the first channel epitaxy 402 and the second channel epitaxy 506.

The conductive gate 602 can be a high-k metal gate (HKMG) formed using, for example, known replacement metal gate (RMG) processes, or so-called gate-last processes. In some embodiments, the conductive gate 602 can include a gate dielectric and a work function metal stack (not separately depicted). While shown as a single gate (i.e., a common gate stack) for ease of illustration and discussion, it should be understood that the conductive gate 602 can include separate gate portions for each region of the substrate 104 (e.g., a first gate stack for the N-TFETs and a second gate stack for the P-TFETs).

In some embodiments, the gate dielectric is a high-k dielectric film formed on a surface (sidewall) of the first channel epitaxy 402 and the second channel epitaxy 506. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments of the invention, the high-k dielectric film can have a thickness of about 0.5 nm to about 4 nm. In some embodiments of the invention, the high-k dielectric film includes hafnium oxide and has a thickness of about 1 nm, although other thicknesses are within the contemplated scope of this disclosure.

The work function metal stack, if present, can include one or more work function layers positioned between the high-k dielectric film and a bulk gate material. In some embodiments, the conductive gate 602 includes one or more work function layers, but does not include a bulk gate material. The work function layers can be made of, for example, aluminum, lanthanum oxide, magnesium oxide, strontium titanate, strontium oxide, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layers can serve to modify the work function of the conductive gate 602 and enables tuning of the device threshold voltage. The work function layers can be formed to a thickness of about 0.5 to 6 nm, although other thicknesses are within the contemplated scope of this disclosure. In some embodiments, each of the work function layers can be formed to a different thickness.

In some embodiments, the conductive gate 602 includes a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate materials can further include dopants that are incorporated during or after deposition.

After forming the conductive gate 602, the semiconductor wafer 100 can be finalized using known processes (e.g., additional FEOL processing, BEOL processing, including the incorporation of a number of Mₓ metallization layers, far back end of line (FBEOL) processing, packaging module(s), etc.,) to define a final device.

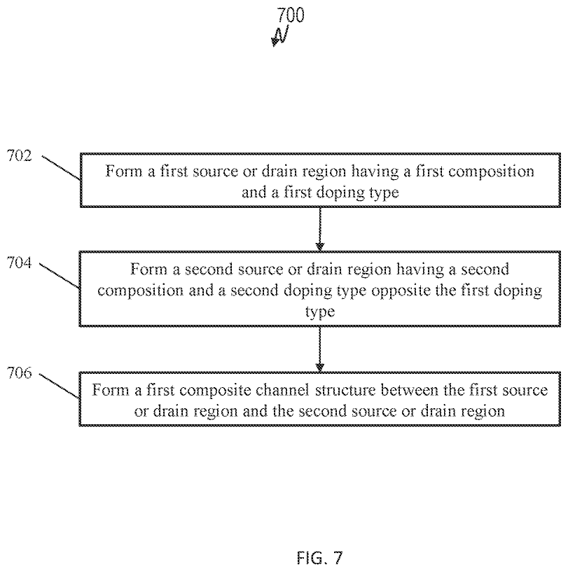

FIG. 7 depicts a flow diagram illustrating a method 700 for the implantation of composite TFETs in a nanosheet process in accordance with one or more embodiments of the invention. As shown at block 702, a first source or drain region is formed having a first composition and a first doping type. At block 704, a second source or drain region is formed having a second composition and a second doping type opposite the first doping type. In some embodiments, the first source or drain region includes N+ doped InGaAs and the second source or drain region includes P+ doped GaAsSb.

At block 706, a first composite channel structure is formed between the first source or drain region and the second source or drain region. The first composite channel structure includes a first nanosheet and a first channel epitaxy. In some embodiments, the first nanosheet is trimmed to expose extension portions of the first source or drain region and extension portions of the second source or drain region. In some embodiments, the first channel epitaxy wraps around the trimmed first nanosheet. In some embodiments, the first channel epitaxy is connected laterally to the extension portions.

The method can further include forming a second composite channel structure opposite the first composite channel structure. The second composite channel structure can include a second nanosheet and a second channel epitaxy. In some embodiments, the second nanosheet is trimmed to expose second extension portions of the first source or drain region and second extension portions of the second source or drain region. In some embodiments, the second channel epitaxy wraps around the trimmed second nanosheet. In some embodiments, the second channel epitaxy is connected laterally to the second extension portions.

In some embodiments, the first channel epitaxy and the second channel epitaxy are formed by epitaxy cladding nucleation. In some embodiments, one or both of the first channel epitaxy and the second channel epitaxy are preferentially grown from a <100> surface of the trimmed first and second nanosheets, respectively.

In some embodiments, the first nanosheet and the second nanosheet are made of a first semiconductor material, the first channel epitaxy is made of a second semiconductor material, and the second channel epitaxy is made of a third semiconductor material. In some embodiments, the first semiconductor material includes silicon, the second semiconductor material includes GaAsSb, and the third semiconductor material includes InGaAs.

In some embodiments, a common gate is formed over the first composite channel structure and the second composite channel structure. In other embodiments, a first gate is formed over the first composite channel structure and a second gate is formed over the second composite channel structure.

In some embodiments, the resultant semiconductor device includes a composite tunnel field effect transistor (TFET).

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a first source or drain region having a first composition and a first doping type;
forming a second source or drain region having a second composition and a second doping type opposite the first doping type; and
forming a first composite channel structure between the first source or drain region and the second source or drain region, the first composite channel structure comprising:
a first nanosheet, the first nanosheet trimmed to expose extension portions of the first source or drain region and extension portions of the second source or drain region; and
a first channel epitaxy wrapping around the trimmed first nanosheet, the first channel epitaxy connected laterally to the extension portions.

2. The method of claim 1, further comprising:
forming a second composite channel structure opposite the first composite channel structure, the second composite channel structure comprising:
a second nanosheet, the second nanosheet trimmed to expose second extension portions of the first source or drain region and second extension portions of the second source or drain region; and
a second channel epitaxy wrapping around the trimmed second nanosheet, the second channel epitaxy connected laterally to the second extension portions.

3. The method of claim 2, wherein the first channel epitaxy and the second channel epitaxy are formed by epitaxy cladding nucleation.

4. The method of claim 3, wherein the first channel epitaxy is preferentially grown from a <100> surface of the trimmed first nanosheet.

5. The method of claim 2, wherein the first nanosheet and the second nanosheet comprise a first semiconductor material, the first channel epitaxy comprises a second semiconductor material, and the second channel epitaxy comprises a third semiconductor material.

6. The method of claim 5, wherein the first semiconductor material comprises silicon, the second semiconductor material comprises GaAsSb, and the third semiconductor material comprises InGaAs.

7. The method of claim 6, wherein the first source or drain region comprises N+ doped InGaAs and the second source or drain region comprises P+ doped GaAsSb.

8. The method of claim 2, further comprising a common gate formed over the first composite channel structure and the second composite channel structure.

9. The method of claim 2, further comprising a first gate formed over the first composite channel structure and a second gate formed over the second composite channel structure.

10. The method of claim 2, wherein the semiconductor device comprises a composite tunnel field effect transistor (TFET).

11. A semiconductor device comprising:
a first source or drain region having a first composition and a first doping type;
a second source or drain region having a second composition and a second doping type opposite the first doping type; and
a first composite channel structure between the first source or drain region and the second source or drain region, the first composite channel structure comprising:
a first nanosheet, the first nanosheet trimmed to expose extension portions of the first source or drain region and extension portions of the second source or drain region; and
a first channel epitaxy wrapping around the trimmed first nanosheet, the first channel epitaxy connected laterally to the extension portions.

12. The semiconductor device of claim 11, further comprising:
a second composite channel structure opposite the first composite channel structure, the second composite channel structure comprising:
a second nanosheet, the second nanosheet trimmed to expose second extension portions of the first source or drain region and second extension portions of the second source or drain region; and
a second channel epitaxy wrapping around the trimmed second nanosheet, the second channel epitaxy connected laterally to the second extension portions.

13. The semiconductor device of claim 12, wherein the first channel epitaxy and the second channel epitaxy are formed by epitaxy cladding nucleation.

14. The semiconductor device of claim 13, wherein the first channel epitaxy is preferentially grown from a <100> surface of the trimmed first nanosheet.

15. The semiconductor device of claim 12, wherein the first nanosheet and the second nanosheet comprise a first semiconductor material, the first channel epitaxy comprises a second semiconductor material, and the second channel epitaxy comprises a third semiconductor material.

16. The semiconductor device of claim 15, wherein the first semiconductor material comprises silicon, the second semiconductor material comprises GaAsSb, and the third semiconductor material comprises InGaAs.

17. The semiconductor device of claim 16, wherein the first source or drain region comprises N+ doped InGaAs and the second source or drain region comprises P+ doped GaAsSb.

18. The semiconductor device of claim 12, further comprising a common gate formed over the first composite channel structure and the second composite channel structure.

19. The semiconductor device of claim 12, further comprising a first gate formed over the first composite channel structure and a second gate formed over the second composite channel structure.

20. The semiconductor device of claim 12, wherein the semiconductor device comprises a composite tunnel field effect transistor (TFET).
